(19) United States
(12) Patent Application Publication
(10) Pub. No.: US 2007/0131925 A1
(43) Pub. Date: Jun. 14, 2007

(54) Organic light-emitting diode

(76) Inventors: Paul Shalk, Bay City, MI (US); Toshio Suzuki, Midland, MI (US); Shihe Xu, Midland, MI (US)

Correspondence Address: DOW CORNING CORPORATION CO1232, 2200 W. SALZBURG ROAD, P.O. BOX 994, MIDLAND, MI, 48686-0994, US

(21) Appl. No.: 10/588,830

(22) PCT Filed: Jan. 18, 2005
(86) PCT No.: PCT/US05/01328

§ 371 Date: Aug. 9, 2006

Related U.S. Application Data
(60) Provisional application No. 60/553,397, filed on Mar. 16, 2004.

(51) Int. Cl. H01L 29/08

(52) U.S. Cl. 257/40

(57) ABSTRACT

An organic light-emitting diode comprising a substrate having a first opposing surface and a second opposing surface; a first electrode layer overlying the first opposing surface; a lightemitting element overlying the first electrode layer, the light-emitting element comprising a hole-transport layer and an emissive/electron-transport layer, wherein the hole-transport layer and the emissive/electron-transport layer lie directly on one another, and the hole-transport layer comprises a cured polysiloxane prepared by applying a silicone composition to form a film and curing the film, wherein the silicone composition comprises a polysiloxane having a group selected from carbazolyl, fluoroalkyl, and pentafluorophenylalkyl; and a second electrode layer overlying the light-emitting element.

### FIELD OF THE INVENTION

The present invention relates to an organic light-emitting diode (OLED) and more particularly to an organic light-emitting diode containing a hole-transport layer comprising a cured polysiloxane prepared by applying a silicone composition to form a film and curing the film, wherein the silicone composition comprises a polysiloxane having a group selected from carbazolyl, fluoroalkyl, and pentafluorophenylalkyl.

### BACKGROUND OF THE INVENTION

Organic light-emitting diodes (OLEDs) are useful in a variety of consumer products, such as watches, telephones, lap-top computers, pagers, cellular phones, digital video cameras, DVD players, and calculators. Displays containing light-emitting diodes have numerous advantages over conventional liquid-crystal displays (LCDs). For example, OLED displays are thinner, consume less power, and are brighter than LCDs. Also, unlike LCDs, OLED displays are self-luminous and do not require backlighting. Furthermore, OLED displays have a wide viewing angle, even in bright light. As a result of these combined features, OLED displays are lighter in weight and take up less space than LCD displays.

OLEDs typically comprise a light-emitting element interposed between an anode and a cathode. The light-emitting element typically comprises a stack of thin organic layers comprising a hole-transport layer, an emissive layer, and an electron-transport layer. However, OLEDs can also contain additional layers, such as a hole-injection layer and an electron-injection layer. Furthermore, the emissive layer can contain a fluorescent dye or dopant to enhance the electroluminscent efficiency of the OLED and control color output.

Although a variety of organic polymers can be used to prepare the hole transport layer in an OLED, poly(3,4-ethylenedioxythiophene)poly(styrenesulfonate), PDOT:PSS, is a preferred hole-transport material. OLEDs containing this material typically have a low turn-on voltage and high brightness. However, a hole-transport layer comprising PDOT:PSS has many limitations including low transparency, high acidity, susceptibility to electrochemical de-doping (migration of dopant from hole-transport layer) and electrochemical decomposition. Moreover, PDOT:PSS is insoluble in organic solvents and aqueous emulsions of the polymer, used to prepare the hole-transport layer, have limited stability. Consequently, there is a need for an OLED comprising a hole-transport layer that overcomes the aforementioned limitations.

### SUMMARY OF THE INVENTION

The present invention is directed to an organic light-emitting diode comprising:
a substrate having a first opposing surface and a second opposing surface;
a first electrode layer overlying the first opposing surface;
a light-emitting element overlying the first electrode layer, the light-emitting element comprising
   a hole-transport layer and
   an emissive/electron-transport layer, wherein the hole-transport layer and the emissive/electron-transport layer lie directly on one another, and the hole-transport layer comprises a cured polysiloxane prepared by applying a silicone composition to form a film and curing the film, wherein the silicone composition comprises (A) a polysiloxane prepared by reacting a silane selected from at least one substituted silane having the formula R¹SiX₃ and a mixture comprising the substituted silane and at least one tetrafunctional silane having the formula SiX₄ with water in the presence of an organic solvent, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group, and (B) an organic solvent; and
a second electrode layer overlying the light-emitting element.

The OLED of the present invention has a low turn-on voltage and high brightness. Also, the hole-transport layer of the present invention, which comprises a cured polysiloxane, exhibits high transparency and a neutral pH. Moreover, the polysiloxane in the silicone composition used to prepare the hole-transport layer is soluble in organic solvents, and the composition has good stability in the absence of moisture.

The organic light-emitting diode of the present invention is useful as a discrete light-emitting device or as the active element of light-emitting arrays or displays, such as flat panel displays. OLED displays are useful in a number of devices, including watches, telephones, lap-top computers, pagers, cellular phones, digital video cameras, DVD players, and calculators.

These and other features, aspects, and advantages of the present invention will become better understood with reference to the following description, appended claims, and accompanying drawings.

### BRIEF DESCRIPTION OF THE DRAWINGS

FIG. 1 shows a cross-sectional view of a first embodiment of an OLED according to the present invention.

FIG. 2 shows a cross-sectional view of a second embodiment of an OLED according to the present invention.

### DETAILED DESCRIPTION OF THE INVENTION

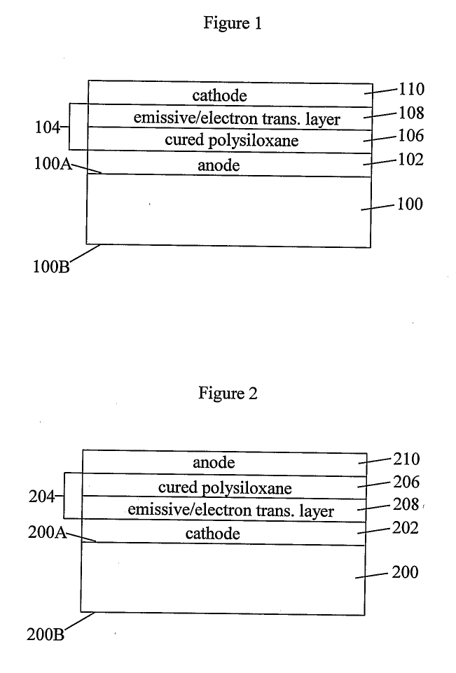

As used herein, the term “overlying” used in reference to the position of the first electrode layer, light-emitting element, and second electrode layer relative to the designated component means the particular layer either lies directly on the component or lies above the component with one or more intermediary layers there between, provided the OLED is oriented with the substrate below the first electrode layer as shown in FIGS. 1 and 2. For example, the term “overlying” used in reference to the position of the first electrode layer relative to the first opposing surface of the substrate in the OLED means the first electrode layer either lies directly on the surface or is separated from the surface by one or more intermediate layers. Further, the term “N-carbazolyl” refers to a group having the formula:

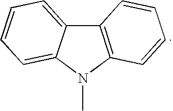

An organic light-emitting diode according to the present invention comprises:
a substrate having a first opposing surface and a second opposing surface;
a first electrode layer overlying the first opposing surface;
a light-emitting element overlying the first electrode layer, the light-emitting element comprising
   a hole-transport layer and
   an emissive/electron-ransport layer, wherein the hole-transport layer and the emissive/electron-transport layer lie directly on one another, and the hole-transport layer comprises a cured polysiloxane prepared by applying a silicone composition to form a film and curing the film, wherein the silicone composition comprises (A) a polysiloxane prepared by reacting a silane selected from at least one substituted silane having the formula R¹SiX₃ and a mixture comprising the substituted silane and at least one tetrafinctional silane having the formula SiX₄ with water in the presence of an organic solvent, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group, and (B) an organic solvent; and
a second electrode layer overlying the light-emitting element.

The substrate has a first opposing surface and a second opposing surface. Also, the substrate can be a rigid or flexible material. Further, the substrate can be transparent or nontransparent to light in the visible region of the electromagnetic spectrum. As used herein, the term “transparent” means the particular component (e.g., substrate or electrode layer) has a percent transmittance of at least 30%, alternatively at least 60%, alternatively at least 80%, for light in the visible region (˜400 to ˜700 nm) of the electromagnetic spectrum. Also, as used herein, the term “nontransparent” means the component has a percent transmittance less than 30% for light in the visible region of the electromagnetic spectrum.

Examples of substrates include, but are not limited to, semiconductor materials such as silicon, silicon having a surface layer of silicon dioxide, and gallium arsenide; quartz; fused quartz; aluminum oxide; ceramics; glass; metal foils; polyolefins such as polyethylene, polypropylene, polystyrene, and polyethyleneterephthalate; fluorocarbon polymers such as polytetrafluoroethylene and polyvinylfluoride; polyamides such as Nylon; polyimides; polyesters such as poly(methyl methacrylate) and poly(ethylene 2,6-naphthalenedicarboxylate); epoxy resins; polyethers; polycarbonates; polysulfones; and polyether sulfones.

The first electrode layer can function as an anode or cathode in the OLED. The first electrode layer may be transparent or nontransparent to visible light. The anode is typically selected from a high work-function (>4 eV) metal, alloy, or metal oxide such as indium oxide, tin oxide, zinc oxide, indium tin oxide (ITO), indium zinc oxide, aluminum-doped zinc oxide, nickel, and gold. The cathode can be a low work-function (<4 eV) metal such as Ca, Mg, and Al; a high work-function (>4 eV) metal, alloy, or metal oxide, as described above; or an alloy of a low-work function metal and at least one other metal having a high or low work-function, such as Mg—Al, Ag—Mg, Al—Li, In—Mg, and Al—Ca. Methods of depositing anode and cathode layers in the fabrication of OLEDs, such as evaporation, co-evaporation, DC magnetron sputtering ,or RF sputtering, are well known in the art.

The light-emitting element layer overlies the first electrode layer. The light-emitting element comprises a hole-transport layer and an emissiveve/electron-transport layer, wherein the hole-transport layer and the emissive/electron-transport layer lie directly on one another, and the hole-transport layer comprises a cured polysiloxane, described below. The orientation of the light-emitting element depends on the relative positions of the anode and cathode in the OLED. The hole-transport layer is located between the anode and the emissive/electron-transport layer and the emissive/electron-transport layer is located between the hole-transport layer and the cathode. The thickness of the hole-transport layer is typically from 2 to 100 nm, alternatively from 30 to 50 nm. The thickness of the emissive/electron-transport layer is typically from 20 to 100 nm, alternatively from 30 to 70 nm.

The hole-transport layer comprises a cured polysiloxane prepared by applying a silicone composition to form a film and curing the film, wherein the silicone composition comprises (A) a polysiloxane prepared by reacting a silane selected from at least one substituted silane having the formula R¹ SiX₃ and a mixture comprising the substituted silane and at least one tetrafinctional silane having the formula SiX₄ with water in the presence of an organic solvent, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group, and (B) an organic solvent. Alternatively, the subscript m is an integer from 2 to 7 or from 2 to 5. Also, alternatively, the subscript n is an integer from 1 to 2.

A silicone composition is applied to the first electrode layer, a layer overlying the first electrode layer, such as a hole-injection layer, or the emissive/electron-transport layer, depending on the configuration of the OLED, to form a film, wherein the silicone comprises components (A) and (B), described below.

Component (A) is at least one polysiloxane prepared by reacting a silane selected from at least one substituted silane having the formula R¹ SiX₃ and a mixture comprising the substituted silane and at least one tetrafunctional silane having the formula SiX₄ with water in the presence of an organic solvent, wherein R¹ is —Y-Cz-, (CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group.

The substituted silane has the formula R¹ SiX₃ with water in the presence of an organic solvent, wherein R¹ is —Y-Cz-, (CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group.

The divalent organic groups represented by Y typically have from 1 to 10 carbon atoms, alternatively from 1 to 6 carbon atoms, alternatively from 1 to 4 carbon atoms. In addition to carbon and hydrogen, the divalent organic groups may contain other atoms such as nitrogen, oxygen, and halogen, provided the divalent group does not inhibit the hydolysis/condensation reaction, described below, used to prepare the polysiloxane. Examples of divalent organic groups represented by Y include, but are not limited to, C₁ to C₁₀ alkylene such as methylene, ethylene, propylene, butylenes, 2-methyl-1,3-propanediyl, and phenylene; halogen-substituted hydrocarbylene such as chloroethylene and fluoroethylene; and alkyleneoxyalkylene such as —CH₂OCH₂CH₂CH₂—, —CH₂CH₂OCH₂CH₂—, —CH₂CH₂OCH(CH₃)CH₂—, and —CH₂OCH₂CH₂OCH₂CH₂—; and carbonyloxyalkylene, such as —C(═O)O—(CH₂)₃—.

Examples of carbazolyl groups represented by R¹ having the formula —Y-Cz, wherein Cz is N-carbazolyl and Y is a divalent organic group, include, but are not limited to, groups having the formulae: —CH₂—CH₂-Cz, (CH₂)₃-Cz, —(CH₂)₄-Cz, —(CH₂)₆-Cz, and —(CH₂)₈-Cz.

Examples of fluoroalkyl groups represented by R¹ having the formula —(CH₂)ₘ—CₙF₂ₙ₊₁, wherein m and n are as defined and exemplified above, include, but are not limited to, groups having the formulae: —CH₂—CH₂—CF₃, —(CH₂)₃—CF₃, —(CH₂)₄—C₂F₅, —(CH₂)₆C₃F₇, and —(CH₂)₈—CF₃.

Examples of pentafluorophenylalkyl groups represented by R¹ having the formula—(CH₂)ₘ—C₆F₅, wherein m is as defined and exemplified above, include, but are not limited to, groups having the formulae: —CH₂—CH₂—C₆F₅, —(CH₂)₃—C₆F₅, —(CH₂)₄—C₆F₅, —(CH₂)₆—C₆F₅, and —(CH₂)₈—C₆F₅.

As used herein, the term “hydrolysable group” means the silicon-bonded group X can react with water to form a silicon-bonded —OH (silanol) group. Examples of hydrolysable groups represented by X include, but are not limited to, —Cl, —Br, —OR², —OCH₂CH₂OR², CH₃C(═O)O—, Et(Me)C═N—O—, CH₃C(═O)N(CH₃)—, and —ONH₂, wherein R² is hydrocarbyl or halogen-substituted hydrocarbyl.

The hydrocarbyl and halogen-substituted hydrocarbyl groups represented by R² typically have from 1 to 8 carbon atoms, alternatively from 3 to 6 carbon atoms. Acyclic hydrocarbyl and halogen-substituted hydrocarbyl groups containing at least 3 carbon atoms can have a branched or unbranched structure. Examples of hydrocarbyl groups include, but are not limited to, unbranched and branched alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, and octyl; cycloalkyl, such as cyclopentyl, cyclohexyl, and methylcyclohexyl; phenyl; alkaryl, such as tolyl and xylyl; aralkyl, such as benzyl and phenethyl; alkenyl, such as vinyl, allyl, and propenyl; arylalkenyl, such as styryl; and alkynyl, such as ethynyl and propynyl. Examples of halogen-substituted hydrocarbyl groups include, but are not limited to, 3,3,3-trifluoropropyl, 3-chloropropyl, chlorophenyl, and dichlorophenyl.

Examples of substituted silanes include, but are not limited to, carbazolyl-substituted silanes such as CzCH₂CH₂SiCl₃, CzCH₂CH₂Si(OCH₃)₃, Cz(CH₂)₃SiCl₃, Cz(CH₂)₄SiCl₃, Cz(CH₂)₆SiCl₃, and Cz(CH₂)₈SiCl₃, wherein Cz is N-carabazolyl; fluoroalkyl-substituted silanes include such as CF₃(CH₂)₂SiCl₃, CF₃(CH₂)₃SiCl₃, CF₃(CH₂)₅SiCl₃, CF₃CF₂(CH₂)₃SiCl₃, CF₃CH₂CH₂Si(OCH₃)₃, CF₃(CH₂)₂Si(OAc)₃, and CF₃CH₂CH₂Si(OCH₂CH₂OCH₃)₃, wherein OAc is acetoxy; and pentafluorphenylalkyl-substituted silanes such as C₆F₅CH₂CH₂SiCl₃, C₆F₅CH₂CH₂Si(OCH₃)₃, C₆F₅(CH₂)₃SiCl₃, C₆F₅(CH₂)₄SiCl₃, C₆F₅(CH₂)₆SiCl₃, and C₆F₅(CH₂)₈SiCl₃.

The substituted silane can be a single silane or a mixture comprising two or more different substituted silanes, each having the formula R¹SiX₃, wherein R¹ and X are as defined and exemplified above.

Methods of preparing fluoroalkyl- and pentafluorophenylalkyl-substituted silanes are well known in the art; many of these silanes are commercially available. Carbazolyl-substituted silanes can be prepared by reacting an N-alkenyl carbazole, for example allyl carbazole, with a tetrafunctional silane, such as trichlorosilane, in the presence of a platinum catalyst, as described in Example 1 below.

The tetrafunctional silane has the formula SiX₄, wherein X is as defined and exemplified above. Examples of tetrafunctional silanes include, but are not limited to, silanes having the formulae: SiCl₄, SiBr₄, Si(OCH₃)₄, Si(OC₂H₅)₄, Si(OCH₂CH₂OCH₃) ₄, Si(OC₃H₇)₄, Si(OAc)₄, and Si[O—N═C(CH₃)CH₂CH₃]₄, wherein OAc is acetoxy. The tetrafunctional silane can be a single silane or a mixture comprising two or more different silanes, each having the formula SiX₄, wherein X is as defined and exemplified above.

The organic solvent can be any nonpolar aprotic or dipolar aprotic organic solvent that does not react with the substituted silane, the tetrafunctional silane, the polysiloxane product, or other components of the reaction mixture under the conditions of the present method, and is miscible with the substituted silane, the tetrafinctional silane, and the polysiloxane. The organic solvent can be immiscible or miscible with water. As used herein, the term “miscible with water” means the organic solvent is completely miscible with the water in the reaction mixture.

Examples of organic solvents include, but are not limited to, aromatic hydrocarbons such as benzene, toluene, xylene and mesitylene; ketones such as methyl isobutyl ketone (MIBK); halogenated alkanes such as trichloroethane; and halogenated aromatic hydrocarbons such as bromobenzene and chlorobenzene; monohydric alcohols such as methanol, ethanol, 1-propanol, and 2-propanol; dihydric alcohols such as ethylene glycol and propylene glycol; polyhydric alcohols such as glycerol and pentaerythritiol; and dipolar aproptic solvents such as N,N-dimethylformamide, tetrahydrofuran, dioxane, dimethylsulfoxide, and acetonitrile. The organic solvent can be a single organic solvent or a mixture comprising two or more different organic solvents, each as defmed above.

The reaction mixture can further comprise at least one hydrolysis catalyst. The hydrolysis catalyst can be any acid catalyst or basic catalyst typically used to catalyze the hydrolysis of organosilanes containing hydrolysable groups that do not react with water to form an acid or a base.

Examples of acid catalysts include, but are not limited to, inorganic acids such as hydrochloric acid, sulfuric acid, nitric acid, and hydrofluoric acid; and organic acids such as acetic acid, oxalic acid, and trifluoroacetic acid. The acid catalyst can be a single acid catalyst or a mixture comprising two or more different acid catalysts.

Examples of alkali catalysts include, but are not limited to, inorganic bases such as ammonium hydroxide; and organic bases such as tetramethylammonium hydroxide, tetrabutylammonium hydroxide, and tetrabutylphosphonium hydroxide. The alkali catalyst can be a single alkali catalyst or a mixture comprising two or more different alkali catalysts.

The reaction can be carried out in any standard reactor suitable for contacting organohalosilanes with water. Suitable reactors include glass and Teflon-lined glass reactors. Preferably, the reactor is equipped with a means of agitation, such as stirring. The reaction can be carried out at atmospheric, subatmospheric, or supraatmospheric pressure. Also, preferably, the reaction is carried out in an inert atmosphere, such as nitrogen or argon.

Typically the silane (i.e., substituted silane, or mixture comprising the substituted silane and the tetrafunctional silane) and water are combined in the presence of the organic solvent by adding water to a mixture of the silane and the organic solvent and mixing the combination. Reverse addition, i.e., addition of the silane to a mixture of water and the organic solvent is also possible.

The rate of addition of water to the mixture of the silane and the organic solvent is typically from 0.5 to 2 mL/min for a 500 mL reaction vessel equipped with an efficient means of stirring. When the rate of addition is too slow, the reaction time is unnecessarily prolonged. When the rate of addition is too fast, very high molecular weight products may be formed.

The reaction is typically carried out at a temperature of from 0 to 60° C., alternatively from room temperature (˜23° C.) to 40° C. When the temperature is less than 0° C., the rate of reaction is typically very slow.

The combination of the silane, water, and organic solvent is mixed for an amount of time sufficient to complete hydrolysis of the hydrolysable groups in the silane. As used herein, the term “to complete hydrolysis” means that at least 98 mol % of the hydrolysable groups, based on the total moles of hydrolysable groups originally present in the silane, are hydrolyzed. The time of mixing depends on a number of factors, such as the type of hydrolysable group X, the structure of the silane, and temperature. The time of mixing is typically from several minutes to several hours. The optimum time of mixing can be determined by routine experimentation using the methods set forth in the Examples section below.

The concentration of the silane is typically from 0.5 to 50% (w/w), alternatively from 0.5 to 30% (w/w), alternatively from 2.5 to 20% (w/w), based on the total weight of the reaction mixture. When the reaction mixture contains the tetrafunctional silane, the concentration of the tetrafunctional silane is typically up to 50 mol %, alternatively up to 30 mol %, alternatively up to 20 mol %, based on the total number of moles of the substituted silane and the tetrafunctional silane.

The concentration of water in the reaction mixture is sufficient to effect hydrolysis of the hydrolysable groups in the silane. The concentration of water depends on the nature of the hydrolysable group X. For example, the concentration of water is typically from 5 to 50 moles, alternatively from 15 to 40 moles, per mole of hydrolysable groups in the silane.

The concentration of the organic solvent is typically from 40 to 90% (w/w), alternatively from 40 to 80% (w/w), alternatively from 50 to 80% (w/w), based on the total weight of the reaction mixture.

When used, the concentration of the hydrolysis catalyst is sufficient to catalyze the hydrolysis of the hydrolysable group X in the silane. For example, the concentration of the hydrolysis catalyst is typically from 0.1 to 10% (w/w), alternatively form 0.1 to 3% (w/w), alternatively from 0.1 to 1% (w/w), based on the total weight of the reaction mixture. When the concentration of the hydrolysis catalyst is less than 0.1% (w/w), the rate of hydrolysis of the hydrolysable groups may be too slow for commercial applications. When the concentration of the acid catalyst is greater than 10% (w/w), additional washings may be required to remove the catalyst.

When the organic solvent used in the method of preparing component (A) is immiscible with water, the polysiloxane can be recovered from the reaction mixture by adding sufficient quantity of an alcohol to effect precipitation of the polysiloxane and then filtering the reaction mixture to obtain the polysiloxane. The alcohol typically has from 1 to 6 carbon atoms, alternatively from 1 to 3 carbon atoms. Moreover, the alcohol can have a linear, branched, or cyclic structure. The hydroxy group in the alcohol may be attached to a primary, secondary, or tertiary aliphatic carbon atom. Examples of alcohols include, but are not limited to, methanol, ethanol, 1-propanol, 2-propanol, 1-butanol, 2-butanol, 2-methyl-1-butanol, 1-pentanol, and cyclohexanol.

Alternatively, the polysiloxane can be recovered from the reaction mixture by separating the organic phase containing the polysiloxane from the aqueous phase, washing the organic phase with water, and then removing the volatile solvent and/or by-products. The organic phase can be separated from the aqueous phase by discontinuing agitation of the mixture, allowing the mixture to separate into two layers, and removing the organic layer.

The organic phase can be washed by mixing it with water, allowing the mixture to separate into two layers, and removing the aqueous layer. The organic phase is typically washed from 4 to 10 times with separate portions of water. The volume of water per wash is typically from 0.5 to 1 times the volume of the organic phase. The mixing can be carried out by conventional methods, such as stirring or shaking.

The volatile solvent and/or by-products can be removed using conventional methods of evaporation. For example, the mixture can be heated under reduced pressure, or heated and purged with an inert gas, such as nitrogen.

When the organic solvent used in the method of preparing component (A) is miscible with water, the polysiloxane can be recovered from the reaction mixture by adding a water-immiscible organic solvent to the reaction mixture with agitation, to form an organic phase containing the polysiloxane and an aqueous phase, separating the organic phase containing the polysiloxane from the aqueous phase, and washing the organic phase with water. The organic phase can be separated from the aqueous phase and washed with water, as described above. A stabilizing agent, such as an alcohol having from 1 to 6 carbon atoms, for example, ethanol, can be added to the solution of the polysiloxane in the water-immiscible organic solvent to improve shelf-stability.

Component (A) can be a single polysiloxane or a mixture comprising two or more different polysiloxanes, each as described above. The concentration of component (A) is typically from 0.5 to 10% (w/w), alternatively from 0.5 to 7% (w/w), alternatively from 2 to 5% (w/w), based on the total weight of the silicone composition.

Component (B) of the silicone composition is at least one organic solvent. The organic solvent can be any nonpolar aprotic or dipolar aprotic organic solvent that does not react with the polysiloxane (component (A)), or other components of the composition, and is miscible with the polysiloxane. The organic solvent typically has a normal boiling point of from 80 to 200° C., alternatively from 90 to 150° C.

Examples of organic solvents include, but are not limited to, aromatic hydrocarbons such as benzene, toluene, xylene and mesitylene; cyclic ethers such as tetrahydrofuran (THF) and dioxane; ketones such as methyl isobutyl ketone (MIBK); halogenated alkanes such as trichloroethane; and halogenated aromatic hydrocarbons such as bromobenzene and chlorobenzene. Component (B) can be a single organic solvent or a mixture comprising two or more different organic solvents, each as defined above.

The concentration of component (B) is typically from 90 to 99.5% (w/w), alternatively from 95 to 98% (w/w), based on the total weight of the silicone composition.

In addition to component (A) and (B), described above, the silicone composition can contain additional ingredients including, but not limited to, condensation catalysts, cross-linking agents, and substituted silanes.

The silicone composition can further comprise at least one condensation catalyst. The condensation catalyst can be any catalyst typically used to promote condensation of silicon-bonded hydroxy (silanol) groups to form siloxane, Si—O—Si, linkages. Examples of condensation catalysts include, but are not limited to, tin(II) and tin(IV) compounds such as tin dilaurate, tin dioctoate, and tetrabutyl tin; and titanium compounds such as titanium tetrabutoxide. The condensation catalyst can be a single condensation catalyst or a mixture comprising two or more different condensation catalysts.

When present, the concentration of the condensation catalyst is typically from 0.1 to 10% (w/w), alternatively from 0.5 to 5% (w/w), alternatively from 1 to 3% (w/w), based on the total weight of the silicone composition.

The silicone composition can further comprise at least one cross-linking agent having the formula R²ₚSiX₄₋ₚ, wherein R² is hydrocarbyl or halogen-substituted hydrocarbyl, X is a hydrolysable group, and p is 0 or 1. The groups represented by R³ and X are as defined and exemplified above. Examples of cross-linking agents include, but are not limited to, chlorosilanes such as SiCl₄, CH₃SiCl₃, CH₃CH₂SiCl₃, and C₆H₅SiCl₃; bromosilanes such as SiBr₄, CH₃SiBr₃, CH₃CH₂SiBr₃, and C₆H₅SiBr₃; alkoxy silanes such as CH₃Si(OCH₃)₃, CH₃Si(OCH₂CH₃)₃, CH₃Si(OCH₂CH₂CH₃)₃, CH₃Si[O(CH₂)₃CH₃]₃, CH₃CH₂Si(OCH₂CH₃)₃, C₆H₅Si(OCH₃)₃, C₆H₅CH₂Si(OCH₃)₃, C₆H₅Si(OCH₂CH₃)₃, CH₂═CHSi(OCH₃)₃, CH₂═CHCH₂Si(OCH₃)₃, CF₃CH₂CH₂Si(OCH₃)₃, CH₃Si(OCH₂CH₂OCH₃)₃, CF₃CH₂CH₂Si(OCH₂CH₂OCH₃)₃, CH₂═CHSi(OCH₂CH₂OCH₃)₃, CH₂═CHCH₂Si(OCH₂CH₂OCH₃)₃, C₆H₅Si(OCH₂CH₂OCH₃)₃, Si(OCH₃)₄, Si(OC₂H₅)₄, and Si(OC₃H₇)₄; organoacetoxysilanes such as CH₃Si(OAc)₃, CH₃CH₂Si(OAc)₃, CH₂═CHSi(OAc)₃, and Si(OAc)₄; organoiminooxysilanes such as CH₃Si[O—N═C(CH₃)CH₂CH₃]₃, Si[O—N═C(CH₃)CH₂CH₃]₄, and CH₂═CHSi[O—N═C(CH₃)CH₂CH₃]₃; organoacetamidosilanes such as CH₃Si[NHC(═O)CH₃]₃ and C₆H₅Si[NHC(═O)CH₃]₃; amino silanes such as CH₃Si[NH(s-C₄H₉)]₃ and CH₃Si(NHC₆H₁₁)₃; and organoaminooxysilanes.

The cross-linking agent can be a single cross-linking agent or a mixture comprising two or more different cross-linking agents, each as described above. Also, methods of preparing tri- and tetra-functional silanes are well known in the art; many of these silanes are commercially available.

When present, the concentration of the cross-linking agent in the silicone composition is sufficient to cure (cross-link) the composition. The exact amount of the cross-linking agent depends on the desired extent of cure, which generally increases as the ratio of the number of moles of silicon-bonded hydrolysable groups in the cross-linking agent to the number of moles of silicon atoms in the polysiloxane, component (A), increases. Typically, the concentration of the of the cross-linking agent is sufficient to provide from 5 to 30 moles of silicon-bonded hydrolysable groups per mole of silicon atoms in the polysiloxane. The optimum amount of the cross-linking agent can be readily determined by routine experimentation.

The silicone composition can further comprise at least one substituted silane having the formula R¹SiX₃, wherein R¹ and X are as defined and exemplified above. Examples of substituted silanes having the formula R¹SiX₃ are as described above. The substituted silane can be a single silane or a mixture of two or more different substituted silanes, each as described above.

When present, the concentration of the substituted silane in the silicone composition is typically from 0.1 to 5% (w/w), alternatively from 0.1 to 3.5% (w/w), alternatively from 0.1 to 2.5% (w/w), based on the total weight of the silicone composition.

The silicone composition of the instant invention is typically prepared by combining components (A) and (B) and any optional ingredients in the stated proportions at ambient temperature. Mixing can be accomplished by any of the techniques known in the art such as milling, blending, and stirring, either in a batch or continuous process. The particular device is determined by the viscosity of the components and the viscosity of the final silicone composition.

The silicone composition can be applied to the first electrode layer, a layer overlying the first electrode layer, or the emissive/electron-transport layer, depending on the configuration of the OLED, to form a film, using conventional methods such as spin-coating, dipping, spraying, brushing, and printing.

The film can be cured by exposing it to heat. The rate of cure depends on a number of factors, including temperature, humidity, and structure of the substituted silane. Partially cured polysiloxanes generally have a higher content of silicon-bonded hydroxy (silanol) groups than more completely cured polysiloxanes. The extent of cure can be varied by controlling cure time and temperature. For example, the silicone composition typically can be cured by exposing the composition to a temperature of from about 50° C. to about 200° C., for period from 0.5 to 72 h.

The emissive/electron-transport layer can be any low molecular weight organic compound or organic polymer typically used as an emissive, electron-transport, electron-injection/electron-transport, or light-emitting material in OLED devices. Low molecular weight organic compounds suitable for use as the electron-transport layer are well known in the art, as exemplified in U.S. Pat. No. 5,952,778; U.S. Pat. No. 4,539,507; U.S. Pat. No. 4,356,429; U.S. Pat. No. 4,769,292; U.S. Pat. No. 6,048,573; and U.S. Pat. No. 5,969,474. Examples of low molecular weight compounds include, but are not limited to, aromatic compounds, such as anthracene, naphthalene, phenanthrene, pyrene, chrysene, and perylene; butadienes such as 1,4-diphenylbutadiene and tetraphenylbutadiene; coumarins; acridine; stilbenes such as trans-stilbene; and chelated oxinoid compounds, such as tris(8-hydroxyquinolato)aluminum(III), Alq_{3.} These low molecular weight organic compounds may be deposited by standard thin-film preparation techniques including vacuum evaporation and sublimation.

Organic polymers suitable for use as the emissive/electron-ransport layer are well known in the art, as exemiplified in U.S. Pat. No. 5,952,778; U.S. Pat. No. 5,247,190; U.S. Pat. No. 5,807,627; U.S. Pat. No. 6,048,573; and U.S. Pat. No. 6,255,774. Examples of organic polymers include, but are not limited to, poly(phenylene vinylene)s, such as poly(1,4 phenylene vinylene); poly-(2,5-dialkoxy-1,4 phenylene vinylene)s, such as poly(2-methoxy-5-(2-ethylhexyloxy)-1,4-phenylenevinylene) (MEHPPV), poly(2-methoxy-5-(2-methylpentyloxy)-1,4-phenylenevinylene), poly(2-methoxy-5-pentyloxy-1,4-phenylenevinylene), and poly(2-methoxy-5-dodecyloxy-1,4-phenylenevinylene); poly(2,5-dialkyl-1,4 phenylene vinylene)s; poly(phenylene); poly(2,5-dialkyl-1,4 phenylene)s; poly(p-phenylene); poly(thiophene)s, such as poly(3-alkylthiophene)s; poly(alkylthienylene)s, such as poly(3-dodecylthienylene); poly(fluorene)s, such as poly(9,9-dialkyl fluorine)s; and polyanilines. Examples of organic polymers also include the polyfluorene-based light-emitting polymers available from The Dow Chemical Company (Midland, Mich.), under the trademark LUMATION, such as LUMATION Red 1100 Series Light-Emitting Polymer, LUMATION Green 1300 Series Light-Emitting Polymer, and LUMATION Blue BP79 Light Emitting Polymer. The organic polymers can be applied by conventional solvent coating techniques such as spin-coating, dipping, spraying, brushing, and printing (e.g., stencil printing and screen printing).

The emissive/electron-transport layer can further comprise a fluorescent dye. Fluorescent dyes suitable for use in OLED devices are well known in the art, as illustrated in U.S. Pat. No. 4,769,292. Examples of fluorescent dyes include, but are not limited to, coumarins; dicyanomethylenepyrans, such as 4-(dicyanomethylene)-2-methyl-6-(p-dimethylaminostyryl)4H-pyran; dicyanomethylenethiopyrans; polymethine; oxabenzanthracene; xanthene; pyrylium and thiapyrylium; cabostyril; and perylene fluorescent dyes.

The second electrode layer can function either as an anode or cathode in the OLED. The second electrode layer may be transparent or nontransparent to light in the visible region. Examples of anode and cathode materials and methods for their formation are as described above for the first electrode layer.

The OLED of the present invention can further comprise a hole-injection layer interposed between the anode and the hole-transport layer, and/or an electron-injection layer interposed between the cathode and the emissive/electron-transport layer. The hole-injection layer typically has a thickness of from 5 to 20 nm, alternatively from 7 to 10 nm. Examples of materials suitable for use as the hole-injection layer include, but are not limited to, copper phthalocyanine. The electron-injection layer typically has a thickness of from 0.5 to 5 mn, alternatively from 1 to 3 mn. Examples of materials suitable for use as the electron-injection layer include, but are not limited to, alkali metal fluorides, such as lithium fluoride and cesium fluoride; and alkali metal carboxylates, such as lithium acetate and cesium acetate. The hole-injection layer and the hole-injection layer can be formed by conventional techniques, thermal evaporation.

As shown in FIG. 1, a first embodiment of an OLED according to the present invention comprises a substrate 100 having a first opposing surface 100A and a second opposing surface 100B, a first electrode layer 102 overlying the first opposing surface 100A, wherein the first electrode layer 102 is an anode, a light-emitting element 104 overlying the first electrode layer 102, wherein the light-emitting element 104 comprises a hole-transport layer 106 and an emissive/electron-transport layer 108 lying directly on the hole-transport layer 106, wherein the hole-transport layer 106 comprises a cured polysiloxane, and a second electrode layer 110 overlying the light-emitting element 104, wherein the second electrode layer 110 is a cathode.

As shown in FIG. 2, a fourth embodiment of an OLED according to the present invention comprises a substrate 200 having a first opposing surface 200A and a second opposing surface 200B, a first electrode layer 202 overlying the first opposing surface 200A, wherein the first electrode layer 202 is a cathode, a light-emitting element 204 overlying the first electrode layer 202, wherein the light-emitting element 204 comprises an emissive/electron-transport layer 208 and a hole-transport layer 206 lying directly on the emissive/electron-transport layer 208, wherein the hole-transport layer 206 comprises a cured polysiloxane, and a second electrode layer 210 overlying the light-emitting element 204, wherein the second electrode layer 210 is an anode.

The OLED of the present invention has a low turn-on voltage and high brightness. Also, the hole-transport layer of the present invention, which comprises a cured polysiloxane, exhibits high transparency and a neutral pH. Moreover, the polysiloxane in the silicone composition used to prepare the hole-transport layer is soluble in organic solvents, and the composition has good stability in the absence of moisture.

The organic light-emitting diode of the present invention is useful as a discrete light-emitting device or as the active element of light-emitting arrays or displays, such as flat panel displays. OLED displays are useful in a number of devices, including watches, telephones, lap-top computers, pagers, cellular phones, digital video cameras, DVD players, and calculators.

### EXAMPLES

The following examples are presented to better illustrate the OLED of the present invention, but are not to be considered as limiting the invention, which is delineated in the appended claims. Unless otherwise noted, all parts and percentages reported in the examples are by weight. The following methods and materials were employed in the examples:

NMR Spectra

Nuclear magnetic resonance spectra (²⁹Si NMR) of polysiloxanes were obtained using a Varian Mercury 400 MHz NMR spectrometer. The polysiloxane (0.5-1.0 g) was dissolved in 2.5-3 mL of acetone-d in a 0.5 oz glass vial. The solution was transferred to a Teflon NMR tube and 3-4 mL of a solution of Cr(acac)₃ in chloroform-d (0.04 M) or acetone-d was added to the tube.

Determination of Molecular Weights

Number-average and weight-average molecular weights (Mₙ and M_{w}) of polysiloxanes were determined by gel permeation chromatography (GPC) using a PLgel (Polymer Laboratories, Inc.) 5-μm column at room temperature (˜23° C.), a ethyl acetate mobile phase at 1 mL/min, and a refractive index detector. Polystyrene standards were used for linear regression calibrations.

Method of Cleaning ITO-Coated Glass Substrates

ITO-coated glass slides (Merck Display Technology, Inc., Taipei, Taiwan) having a surface resistance of 30 Ω/square were cut into 25-mm square substrates. The substrates were inmersed in an ultrasonic bath containing a solution consisting of 1% Alconox powdered cleaner (Alconox, Inc.) in water for 10 min and then rinsed with deionized water. The substrates were then immersed sequentially in the each of the following solvents with ultrasonic agitation for 10 min in each solvent: isopropyl alcohol, n-hexane, and toluene. The glass substrates were then dried under a stream of dry nitrogen. Immediately before use, the substrates were treated with oxygen plasma for 3 min.

Deposition of SiO in OLEDs

Silicon monoxide (SiO) was deposited by thermal evaporation using a BOC Edwards Auto 306 high vacuum deposition system equipped with a crystal balance film thickness monitor. The substrate was placed in a rotary sample holder positioned above the source and covered with the appropriate mask. The source was prepared by placing a sample of SiO in an aluminum oxide crucible. The crucible was then positioned in a tungsten wire spiral. The pressure in the vacuum chamber was reduced to 2.0×10⁻⁶ mbar. The substrate was allowed to outgas for at least 30 min at this pressure. The SiO film was deposited by heating the source via the tungsten filament while rotating the sample holder. The deposition rate (0.1 to 0.3 nm per second) and the thickness of the film were monitored during the deposition process.

Deposition of LiF, Ca, and Al Films in OLEDs

Lithium fluoride, calcium, and aluminum films were deposited by thermal evaporation under an initial vacuum of 10⁻⁶ mbar using a BOC Edwards model E306A Coating System equipped with a crystal balance film thickness monitor. The source was prepared by placing the metal in an aluminum oxide crucible and positioning the crucible in a tungsten wire spiral, or by placing the metal directly in a tungsten basket. When multiple layers of different metals were required, the appropriate sources were placed in a turret that could be rotated for deposition of each metal. The deposition rate (0.1 to 0.3 nm per second) and the thickness of the film were monitored during the deposition process.

LUMATION Blue BP79 Light Emitting Polymer, available from The Dow Chemical Company (Midland, Mich.), is a polyfluorene polymer that emits light in the blue region of the visible spectrum.

### Example 1

Trichlorosilane (4.47 g), 5.52 g of allyl carbazole, and 5.5 g of anhydrous toluene were combined under nitrogen in a one-neck glass flask equipped with a magnetic stir bar. To the mixture was added 0.015 g of a solution consisting of 0.31% of 1,3-divinyl-1,1,3,3-tetramethyldisiloxane and 0.19% of a platinum complex of 1,3-divinyl-1,1,3,3-tetramethyldisiloxane in dry toluene. The mixture was heated under nitrogen at 60° C. for 1 h and then flushed with dry nitrorgen at 60° C. for 10 min. The mixture was then distilled at about 220° C. under vacuum to produce 3-(N-carbazolyl)propyltrichlorosilane) as a colorless fluid, which formed transparent colorless crystals upon cooling to room temperature.

A portion (0.5 g) of the 3-(N-carbazolyl)propyltrichlorosilane) was dissolved in 9.5 g of toluene in a glass vial. A drop of the solution was applied to double-polished silicon wafer and the solvent was evaporated under a stream of dry nitrogen to form a thin film (4 μm). The FTIR spectrum of the film showed absorptions characteristic of the carbazole ring at 1598, 1484, 1452, 750 and 722 cm⁻¹, Si—Cl absorptions at 564, 589, and 696 cm⁻¹. No Si—OH or Si—O—Si absorptions were observed. The film was exposed to ambient air (30% RH) for 0.5 h, after which the Si—Cl absorptions were nearly absent, and a broad Si—O—S absorption centered at 1050 cm⁻¹ and a broad SiOH absorption centered at 3400 cm⁻¹ were observed. The film was heated at 100° C. for 60 min, after which a weak SiOH absorption was observed in the FTIR spectrum.

### Example 2

3-(N-Carbazolyl)propyltichlorosilane (10 g), prepared as described in Example 1, 10 g of toluene and 10 g of deionized water were combined in a one-neck glass flask equipped with a magnetic stir bar. The mixture was stirred vigorously for 2 h and substantial heat was produced initially. After stirring was discontinued, the mixture separated into two phases. The aqueous phase was removed and the organic phase was washed with 30 mL of deionized water to remove acid. This washing step was repeated until the pH of the wash was greater than 6. The organic mixture was dried under vacuum at room temperature to obtain a polysiloxane as a brownish solid. The polysiloxane had a number-average molecular weight and a weight-average molecular weight of 2110 and 2780, respectively. The composition of the polysiloxane, as determined by ²⁹si NMR, was
[Cz(CH₂)₃Si(OH)O_{2/2}]_{0.56}[Cz(CH₂)SiO_{3/2}]_{0.44}.

### Example 3

3,3,3-Trifluoropropyltrichlorosilane (10 g), 10 g of methyl isobutyl ketone, and 10 g of deionized water were combined in a glass flask equipped with a magnetic stir bar. The mixture was stirred vigorously for 2 hr and substantial heat was produced initially. After stirring was discontinued, the mixture separated into two phase. The aqueous phase was removed and the organic phase was washed with 30 mL of deionized water to remove acid. This washing step was repeated until the pH of the wash was greater than 6. The organic mixture was dried under vacuum at room temperature to obtain a polysiloxane as a brownish solid. The polysiloxane had a number-average molecular weight and a weight-average molecular weight of 2110 and 2780, respectively. The composition of the polysiloxane, as determined by ²⁹Si NMR, was
[F₃C(CH₂)₃Si(OH)O_{2/2}]_{0.34}[F₃C(CH₂)₃SiO_{3/2}]_{0.66}.

### Example 4

Allyl carbazole (10 g), 6.3 g of trichlorosilane, and 20 g of methyl isobutyl ketone were combined under nitrogen in a glass flask equipped with a magnetic stirrer. To the mixture was added 0.04 g of a solution consisting of 0.31% of 1,3-divinyl-1,1,3,3-tetramethyldisiloxane and 0.19% of a platinum complex of 1,3-divinyl-1,1,3,3-tetramethyldisiloxane in dry toluene. The mixture was heated to 60 C for 1 hr and then 5.01 g of 3,3,3-trifluoropropyltrichlorosilane was added into the flask. Deionized water (20 mL) was added dropwise to the mixture with vigorous stirring. After the addition was complete, an additional 30 mL of deionized water was added to the mixture. After being stirring for 1 hr, the mixture was allowed to separated into two phases. The aqueous phase was removed and the organic phase was washed with 50 mL of deionized water. This washing step was repeated until the pH of the wash was greater than 6. The organic mixture was then dried under vacuum at room temperature to obtain a polysiloxane as a brownish solid. The polysiloxane had a number-average molecular weight and a weight-average molecular weight of 1530 and 1910, respectively. The composition of the polysiloxane, as determined by ²⁹Si NMR, was
[Cz(CH₂)₃Si(OH)O_{2/2}F₃C(CH₂)₂Si(OH)O_{2/2}]_{0.55}[Cz(CH₂)₃SiO_{3/2}F₃C(CH₂)₂SiO_{3/2}]₀.45.

### Example 5

Four OLEDs (see figures below) were fabricated as follows: Silicon monoxide (100 nm) was thermally deposited along a first edge of a pre-cleaned ITO-coated glass substrate (25 mm×25 mm) through a mask having a rectangular aperture (6 mm×25 mm). A strip of 3M Scotch brand tape (5 mm×25 mm) was applied along a second edge of the substrate, perpendicular to the SiO deposit. A solution consisting of 2% of the polysiloxane of Example 4 and 0.2% of tetraacetoxysilane in 1-methoxy-2-propanol was spin-coated (1000 rpm, 20 s) over the ITO surface using a CHEMAT Technology Model KW-4A spin-coater to form a hole-transport layer having a thickness of 40 nm. The composite was heated in an oven under nitrogen at 50° C. for 1 h, 100° C. for 0.5 h, 130° C. for 1 h, and 200° C. for 1.5 h. A solution consisting of 1.5 wt % of LUMATION Blue BP79 Light-Emitting Polymer in xylene was then spin-coated (2250 rpm, 40 second) over the hole-transport layer to form an emissive/electron-transport layer having a thickness of 50 um. The composite was heated in an oven under nitrogen at 100° C. for 30 min and then allowed to cool to room temperature. The strip of tape was removed from the substrate to expose the anode (ITO) and four cathodes were formed by depositing lithium fluoride (1 nm), calcium (50 nm) and aluminum (150 nm) sequentially on top of the light-emitting polymer layer and SiO deposit through a mask having four rectangular apertures (3 mm×16 mm). Each of the four OLEDs emitted a blue color light and had a turn-on voltage at 1 cd m⁻² of about 4.4 V, a brightness at 10 V of approximately 6770 cd m⁻², and a peak luminous efficiency of 2.7 cd A⁻¹.

[image]

Four OLEDs were fabricated as described in Example 5, with the following exceptions: The hole-ransport layer was prepared using a solution consisting of 3% of 3-(N-carbazolyl)propyltrichlorosilane), 3% of the polysiloxane of Example 4, and 0.6% of tetraacetoxysilane in toluene. Also, the emissive/electron transport layer was formed using a 1.5% solution of LUMATION Blue BP79 Light-Emitting Polymer in mesitylene. Each of the four OLEDs emitted a blue color light and had a turn-on voltage at 1 cd m⁻² of about 2.8 V, brightness at 10 V of approximately 12000 cd m⁻², and a peak luminous efficiency of 5.9 cd A⁻¹.

### Example 7

Four OLEDs (see figures below) were fabricated as described in Example 5, with the following exceptions: The hole-transport layer was prepared by spin-coating (4,200 rpm, 20 s) a solution consisting of 5% of the polysiloxane of Example 3 in methyl isobutyl ketone over the ITO surface to form a hole-ransport layer having a thickness of 40 nm. The composite was heated in an oven under nitrogen at 50° C. for 1 h, 100° C. for 0.5 h, and 130° C. for 1 h. A solution consisting of 1.5 wt % of LUMATION Blue BP79 Light-Emitting Polymer in mesitylene was then spin-coated (2250 rpm, 40 second) over the hole-transport layer to form an emissive/electron-transport layer having a thickness of 50 nm. Each of the four OLEDs emitted a blue color light and had a turn-on voltage at 1 cd m⁻² of about 3.4 V, a brightness at 10 V of approximately 4400 cd m⁻², and a peak luminous efficiency of 1.6 cd A⁻¹.

That which is claimed is:

1. An organic light-emitting diode comprising:
a substrate having a first opposing surface and a second opposing surface;
a first electrode layer overlying the first opposing surface;
a light-emitting element overlying the first electrode layer, the light-emitting element comprising
a hole-transport layer and
an emissive/electron-transport layer, wherein the hole-transport layer and the emissive/electron-transport layer lie directly on one another, and the hole-transport layer comprises a cured polysiloxane prepared by applying a silicone composition to form a film and curing the film, wherein the silicone composition comprises (A) a polysiloxane prepared by reacting a silane selected from at least one substituted silane having the formula R¹SiX₃ and a mixture comprising the substituted silane and at least one tetrafunctional silane having the formula SiX₄ with water in the presence of an organic solvent, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group, and (B) an organic solvent; and
a second electrode layer overlying the light-emitting element.

2. The organic light-emitting diode according to claim 1, wherein the silane of component (A) is at least one substituted silane having the formula R¹ SiX₃, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group.

3. The organic light-emitting diode according to claim 1, wherein the silane of component (A) is a mixture comprising at least one substituted silane having the formula R¹ SiX₃ and at least one tetrafunctional silane having the formula SiX₄, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group.

4. The organic light-emitting diode according to claim 1, wherein the organic solvent of component (A) is immiscible with water.

5. The organic light-emitting diode according to claim 1, wherein the organic solvent of component (A) is miscible with water.

6. The organic light-emitting diode according to claim 1, wherein the reaction mixture for preparing the polysiloxane further comprises at least one hydrolysis catalyst.

7. The organic light-emitting diode according to claim 1, wherein the silicone composition further comprises at lest one cross-linking agent having the formula R²ₚSiX₄₋ₚ, wherein R² is hydrocarbyl or halogen-substituted hydrocarbyl, X is a hydrolysable group, and p is 0 or 1.

8. The organic light-emitting diode according to claim 1, wherein the silicone composition further comprises at lest one silane having the formula R¹SiX₃, wherein R¹ is —Y-Cz, —(CH₂)ₘ—CₙF₂ₙ₊₁, or —(CH₂)ₘ—C₆F₅, wherein Cz is N-carbazolyl, Y is a divalent organic group, m is an integer from 2 to 10, n is an integer from 1 to 3, and X is a hydrolysable group.

9. The organic light-emitting diode according to claim 1, wherein the emmisive/electron transport layer comprises a fluorescent dye.

10. The organic light-emitting diode according to claim 1, further comprising at least one of a hole-injection layer and an electron injection layer.
